(19) United States
(12) Patent Application Publication
(10) Pub. No.: US 2015/0194472 A1
(43) Pub. Date: Jul. 9, 2015

(54) PIXEL STRUCTURE FOR DISPLAY PANEL AND DISPLAY PANEL

(71) Applicant: EverDisplay Optronics (Shanghai) Limited, Shanghai (CN)

(72) Inventors: Tsungyi SU, Shanghai (CN); Yujen CHEN, Shanghai (CN)

(21) Appl. No.: 14/592,514

(22) Filed: Jan. 8, 2015

(30) Foreign Application Priority Data
Jan. 9, 2014 (CN) 201410010273.4

(51) Int. Cl. H01L 27/32

(52) U.S. Cl. CPC H01L 27/3218; H01L 27/3276

(57) ABSTRACT

The present disclosure provides a pixel structure for a display panel and a display panel. The pixel structure includes a pixel, a first scan line, a second scan line, a first data line and a second data line. The pixel includes a first sub-pixel, a second-sub pixel and a third sub-pixel. The first scan line is coupled to the first sub-pixel and the second sub-pixel; the second scan line is coupled to the third sub-pixel; the first data line is coupled to the first sub-pixel and the third sub-pixel; and the second data line is coupled to the second sub-pixel. By employing the pixel structure for a display panel according to the present disclosure, a layout of three sub-pixels are more reasonable, and the problem that the existing RGB arrangement structure of pixels results in too small traverse width of sub-pixels is solved.

### CROSS REFERENCE TO RELATED APPLICATIONS

The present application claims priority under 35 U.S.C. §119 to Chinese Patent Applications No. 201410010273.4, filed on Jan. 9, 2014, the entire contents of which are incorporated herein by reference.

### TECHNICAL FIELD

The present disclosure generally relates to the field of manufacturing an Organic Light Emitting Diode (OLED) display panel, and more particularly to a pixel arrangement structure for an OLED display panel.

### BACKGROUND

FIG. 1 is a schematic diagram showing a RGB arrangement structure of pixels of an existing OLED display panel. This structure is a traditional side-by-side arrangement, also called as a real-strip pixel arrangement. In the side-by-side arrangement shown in FIG. 1, the OLED display panel includes pixel units arranged in a plurality of rows and a plurality of columns, and each pixel unit includes three parallel sub-pixels, i.e., a red (R) sub-pixel, a green (G) sub-pixel and a blue (B) sub-pixel.

As shown in FIG. 1, in the existing pixel design, one horizontal scan line matches three data lines which are perpendicular to the scan line and correspond to the red sub-pixel R, the green sub-pixel G and the blue sub-pixel B respectively.

However, when such pixel arrangement is applied in a panel with high resolution, a horizontal width of each sub-pixel will be too small. Thus, such structure is not good for matching design of TFT with high resolution. Taking 5″440 (PPI) resolution as an example, a 19 μm pixel width is given to each of the sub-pixels of three primary colors, and this is prone to bring adverse effect to yield rate of TFT process. In addition, the pixel arrangement shown in FIG. 1 has a high data line overhead.

Therefore, a solution that is beneficial for improving resolution and reducing data line overhead is desired.

The above information disclosed in the background portion is only for the purposes of enhancing understanding of the background of the present disclosure, and thus it may include information which does not constitute prior art known to one of ordinary skill in this art.

### SUMMARY

The present disclosure provides a RGB arrangement structure of pixels for a display panel to solve the problem that the existing RGB arrangement structure of pixels results in too small traverse width of sub-pixels and is prone to bring adverse effect to yield rate of TFT process.

A pixel structure for a display panel according to the present disclosure includes: a pixel including a first sub-pixel, a second sub-pixel and a third sub-pixel; a first scan line configured to provide a scan signal to the first sub-pixel and the second sub-pixel; a second scan line configured to provide a scan signal to the third sub-pixel; a first data line configured to provide pixel data to the first sub-pixel and the third sub-pixel; and a second data line configured to provide pixel data to the second sub-pixel; wherein the first scan line is coupled to the first sub-pixel and the second sub-pixel, the second scan line is coupled to the third sub-pixel, the first data line is coupled to the first sub pixel and the third sub pixel, and the second data line is coupled to the second sub-pixel.

According to an embodiment of the pixel arrangement structure for a display panel of the present disclosure, the first scan line and the second scan line are parallel to each other, the first data line and the second data line are parallel to each other, and the first scan line and the second scan line are perpendicular to the first data line and the second data line.

According to an embodiment of the pixel arrangement structure for a display panel of the present disclosure, the first sub-pixel and the second sub-pixel are arranged in a first direction and the first sub-pixel and the third sub-pixel are arranged in a second direction perpendicular to the first direction. According to an embodiment, the first direction is a direction in parallel with the first and second scan line, and the second direction is a direction in parallel with the first and second data line. According to an embodiment, the first direction is a horizontal direction, and the second direction is a vertical direction.

According to an embodiment of the pixel arrangement structure for a display panel of the present disclosure, each of the first sub-pixel, the second sub-pixel and the third sub-pixel has a width which is half of a width of the pixel.

According to an embodiment of the pixel arrangement structure for a display panel of the present disclosure, the first sub-pixel, the second sub-pixel and the third sub-pixel are a red sub-pixel, a green sub-pixel and a blue sub-pixel, respectively.

According to an embodiment of the pixel arrangement structure for a display panel of the present disclosure, a scan frequency of the first scan line and the second scan line is 120 hz.

The present disclosure further discloses a display panel including a plurality of pixels, each of the pixels has the pixel structure as described above. In the display panel, the plurality of pixels are arranged at equal intervals in a horizontal direction and a vertical direction.

In sum, in the present disclosure, by arranging a blue sub-pixel, a red sub-pixel and a green sub-pixel in a unit pixel to form S-stripe, and by performing scanning with two scan lines, a layout of the three sub-pixels are more reasonable, and thus the problem that the existing RGB arrangement structure of pixels results in too small traverse width of sub-pixels is solved.

### BRIEF DESCRIPTION OF THE DRAWINGS

FIG. 1 is a schematic diagram showing a pixel structure for an existing display panel.

FIG. 2 is a schematic diagram showing a pixel arrangement structure for a display panel according to an exemplary embodiment of the present disclosure.

FIG. 3 is a timing sequence diagram corresponding to FIG. 2.

FIG. 4 is a pixel arrangement diagram showing a display panel according to the present disclosure.

### DETAILED DESCRIPTION

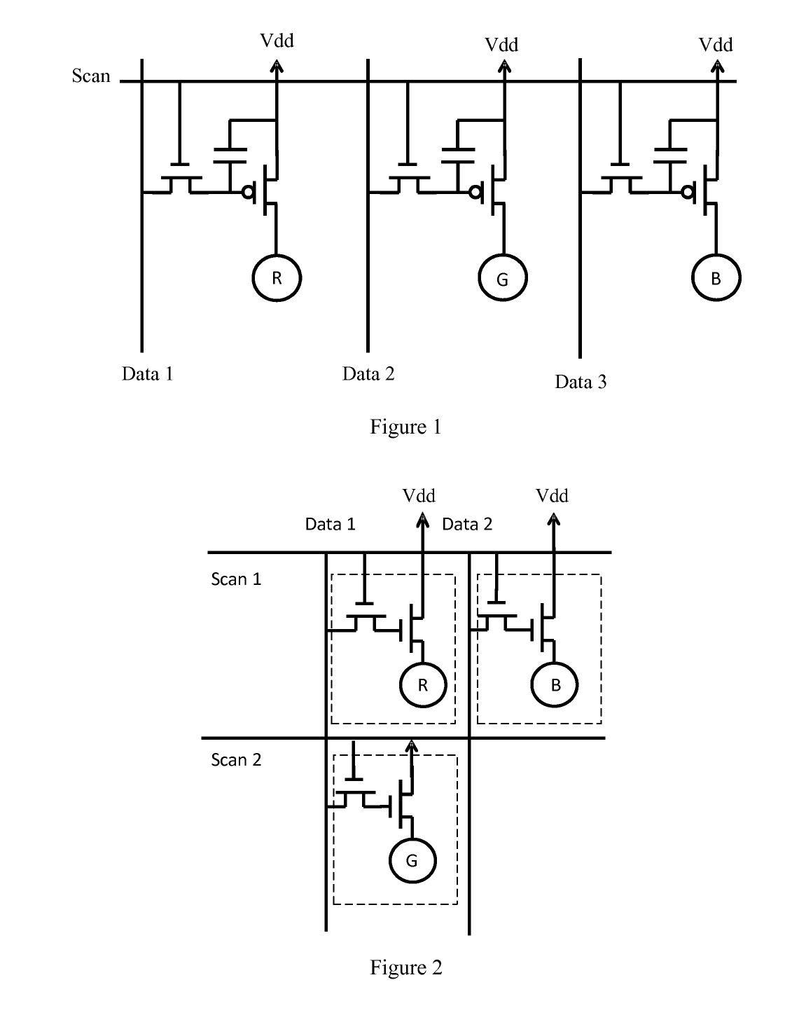

FIG. 2 is a schematic diagram showing a pixel arrangement structure for a display panel according to an exemplary embodiment of the present disclosure. The RGB arrangement structure of the embodiment is explained by taking a unit pixel as example. Referring to FIG. 2, the shown pixel arrangement structure includes a red sub-pixel R, a green sub-pixel G, a blue sub-pixel B, a data line Data 1, a data line Data 2, a scan line Scan 1, and a scan line Scan 2.

Referring to FIG. 2, the three sub-pixels, i.e., the red sub-pixel R, the green-sub pixel G and the blue sub-pixel B, are arranged as a triangular. Specifically, in the exemplary embodiment of the present disclosure, the pixel structure includes unit pixels arranged in a plurality of rows and a plurality of columns, each unit pixel includes the red sub-pixel R, the green sub-pixel G and the blue-sub pixel B. The red sub-pixel R and the green sub-pixel G are arranged at one side of the blue sub-pixel B, and the red sub-pixel R and the green sub-pixel G are arranged in a vertical direction up and down to form a column.

According to an embodiment, each of the red sub-pixel R, the green sub-pixel G and the blue sub-pixel B may be, for example, a rectangle. According to another embodiment, the blue sub-pixel B may be, for example, a rectangle, and each of the red sub-pixel R and the green sub-pixel G may be, for example, a square.

An area of the blue sub-pixel B may be, for example, greater than the area of either of the red sub-pixel R and the green sub-pixel G.

Referring to FIG. 2, the data line Data 1 is coupled to the red sub-pixel R and the green sub-pixel G. The data line Data 2 is coupled to the blue sub-pixel B. The scan line Scan 1 is coupled to the red sub-pixel R and the green sub-pixel B. The scan line Scan 2 is coupled to the green sub-pixel G.

Further, referring to FIG. 2, for a preferred embodiment, the RGB arrangement of the unit pixel may be that the scan line Scan 1 and the scan line Scan 2 are parallel to each other, the data line Data 1 and the data line Data 2 are parallel to each other, and the data line Data 1 and the data line Data 2 are perpendicular to the scan line Scan 1 and the scan line Scan 2.

Further, referring to FIG. 2, a horizontal length of an existing unit pixel with 5″440 resolution is generally 57 μm. Therefore, in the present embodiment, since the green sub-pixel G is under the red sub-pixel R, each of the red sub-pixel R and the blue sub-pixel B occupies a traverse length of 28.5 um. However, in the existing unit pixel with 5″440 resolution, since the red sub-pixel R, the blue sub-pixel B and the green sub-pixel G are arranged in one row, the horizontal length of each sub-pixel is 19 μm. Consequently, the arrangement according the present disclosure may increase horizontal lengths of sub-pixels.

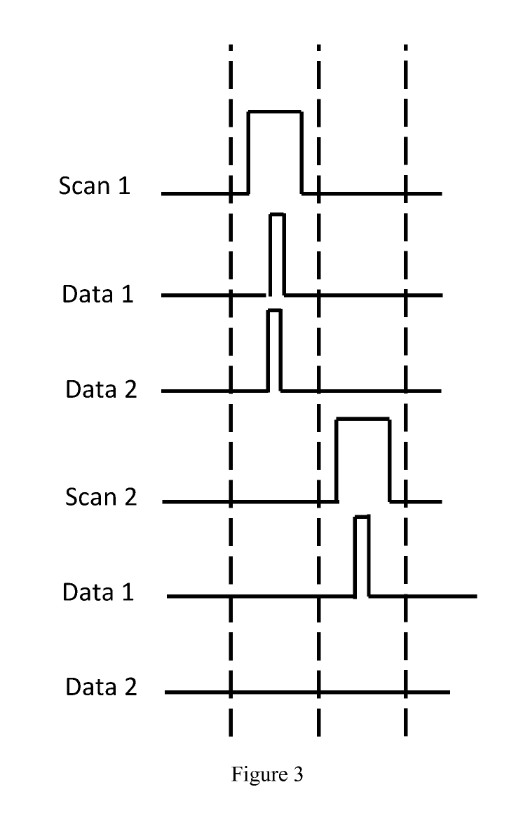

FIG. 3 is a timing sequence diagram corresponding to FIG. 2. Referring to FIG. 3, in one excitation cycle of a unit pixel, after a scan signal of the scan line Scan 1 becomes a high level, the data line Data 1 and the data line Data 2 are simultaneously at the high level to provide pixel data to the red sub-pixel R and the blue sub-pixel B. That is, the red sub-pixel R and the blue sub-pixel B in FIG. 2 are exited; after the scan signal of the scan line Scan 1 is lowered to a low level and a scan signal of the scan line Scan 2 is raised to a high level, the data line 1 is at the high level to provide pixel data to the green sub-pixel G, and the data line Data 2 is at a low level. At this time, the green sub-pixel G shown in FIG. 2 is exited. Thus, one excitation cycle of the unit pixel is completed.

It can be seen from the above that, in the RGB arrangement structure for pixels according to the present disclosure, since the number of the scan lines is two, the two scan lines need to be at a high level respectively in one excitation cycle of a unit pixel, and this is different from the exiting RGB arrangement structure with a single scan line. Therefore, a frequency of each of the scan line Scan 1 and the scan line Scan 2 according to the present disclosure should be two times of that of the existing single scan line. The frequency of the exiting scan line is 60 hz, and thus the frequency of each of the scan line Scan 1 and the scan line Scan 2 according to the present disclosure is 120 hz.

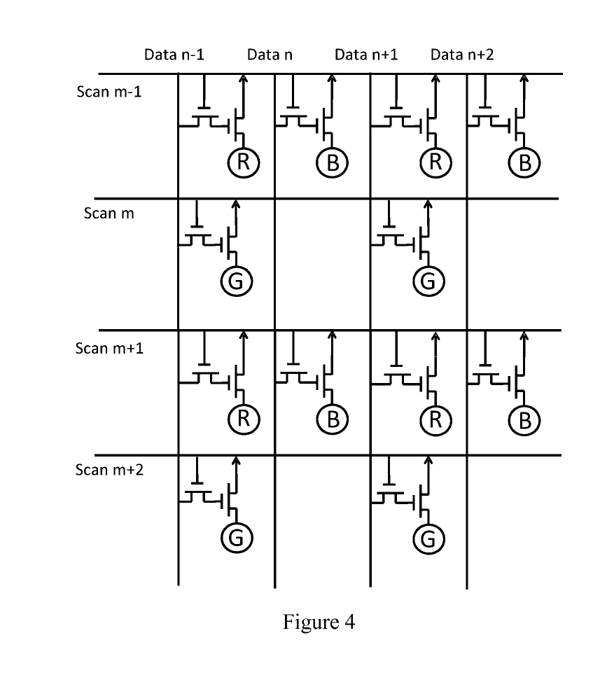

FIG. 4 is a pixel arrangement diagram showing a display panel according to the present disclosure. The pixel arrangement structure of a display panel according to the present disclosure is explained by taking an arrangement of four unit pixels as an example in this embodiment. As shown in FIG. 4, the pixel arrangement structure includes a scan line Scan m−1, a scan line Scan m, a scan line Scan m+1, a scan line Scan m+2, a data line Data n−1, a data line Data n, a data line Data n+1, a data line Data n+2 and sub-pixels of four pixels. In addition, as shown in FIG. 4, the arrangement structure of a plurality of pixels in this embodiment is that the plurality of pixels are arranged in parallel in a horizontal direction and a vertical direction. One scan line (for example, the scan line Scan m−1) corresponds to two red sub-pixels R and two blue sub-pixels B of two pixels in a first row. And one data line (for example, the data line Data n−1) corresponds to two red sub-pixels R and two green sub-pixels G of two pixels in a first column.

In sum, in the present disclosure, by arranging a blue sub-pixel, a red sub-pixel and a green sub-pixel in a unit pixel to form S-stripe, and by performing scanning with two scan lines, a layout of the three sub-pixels are more reasonable, and thus the problem that the existing RGB arrangement structure of pixels results in too small traverse width of sub-pixels is solved.

Although the present disclosure has been described with reference to several general embodiments, it should be understood that, the terms used herein are illustrative and exemplary terms, not limiting terms. Since the present disclosure may be practiced specifically in various forms without departing from the spirit of substance of the present disclosure, it should be understood that, the above embodiments are not limited to the details described above, but should be interpreted broadly within the spirit and scope defined by appended claims. Therefore, all the variations and modifications falling into scope of the claims or of the equivalent thereof should be covered by the appended claims.

What is claimed is:

1. A pixel structure for a display panel, comprising:
a pixel comprising a first sub-pixel, a second sub-pixel and a third sub-pixel;
a first scan line configured to provide a first scan signal to the first sub-pixel and the second sub-pixel;
a second scan line configured to provide a second scan signal to the third sub-pixel;
a first data line configured to provide first pixel data to the first sub-pixel and the third sub-pixel; and
a second data line configured to provide second pixel data to the second sub-pixel;
wherein the first scan line is coupled to the first sub-pixel and the second-sub pixel, the second scan line is coupled to the third sub-pixel, the first data line is coupled to the first sub-pixel and the third sub-pixel, and the second data line is coupled to the second sub-pixel.

2. The pixel structure for a display panel of claim 1, wherein the first scan line and the second scan line are parallel to each other, the first data line and the second data line are parallel to each other, and the first scan line and the second scan line are perpendicular to the first data line and the second data line.

3. The pixel structure for a display panel of claim 1, wherein the first sub-pixel and the second sub-pixel are arranged in a first direction, and the first sub-pixel and the third sub-pixel are arranged in a second direction perpendicular to the first direction.

4. The pixel structure for a display panel of claim 3, wherein the first direction is a direction in parallel with the first and second scan lines, and the second direction is a direction in parallel with the first and second data line.

5. The pixel structure for a display panel of claim 4, wherein the first direction is a horizontal direction, and the second direction is a vertical direction.

6. The pixel structure for a display panel of claim 3, wherein each of the first sub-pixel, the second sub-pixel and the third sub-pixel has a width which is half of a width of the pixel.

7. The pixel structure for a display panel of claim 4, wherein each of the first sub-pixel, the second sub-pixel and the third sub-pixel has a width which is half of a width of the pixel.

8. The pixel structure for a display panel of claim 1, wherein the first sub-pixel, the second sub-pixel and the third sub-pixel are a red sub-pixel, a green sub-pixel and a blue sub-pixel, respectively.

9. The pixel structure for a display panel of claim 2, wherein the first sub-pixel, the second sub-pixel and the third sub-pixel are a red sub-pixel, a green sub-pixel and a blue sub-pixel, respectively.

10. The pixel structure for a display panel of claim 1, wherein the first scan line and the second scan line has a scan frequency of 120 hz.

11. A display panel comprising a plurality of pixels, wherein each of the pixels has a pixel structure which comprises:
a pixel comprising a first sub-pixel, a second sub-pixel and a third sub-pixel;
a first scan line configured to provide a first scan signal to the first sub-pixel and the second sub-pixel;
a second scan line configured to provide a second scan signal to the third sub-pixel;
a first data line configured to provide first pixel data to the first sub-pixel and the third sub-pixel; and
a second data line configured to provide second pixel data to the second sub-pixel;
wherein the first scan line is coupled to the first sub-pixel and the second-sub pixel, the second scan line is coupled to the third sub-pixel, the first data line is coupled to the first sub-pixel and the third sub-pixel, and the second data line is coupled to the second sub-pixel;
wherein the plurality of pixels are arranged at equal intervals in a horizontal direction and a vertical direction.

12. The display panel of claim 11, wherein the first scan line and the second scan line are parallel to each other, the first data line and the second data line are parallel to each other, and the first scan line and the second scan line are perpendicular to the first data line and the second data line.

13. The display panel of claim 11, wherein the first sub-pixel and the second sub-pixel are arranged in a first direction, and the first sub-pixel and the third sub-pixel are arranged in a second direction perpendicular to the first direction.

14. The display panel of claim 13, wherein the first direction is a direction in parallel with the first and second scan line, and the second direction is a direction in parallel with the first and second data line.

15. The display panel of claim 14, wherein the first direction is a horizontal direction, and the second direction is a vertical direction.

16. The display panel of claim 13, wherein each of the first sub-pixel, the second sub-pixel and the third sub-pixel has a width which is half of a width of the pixel.

17. The display panel of claim 14, wherein each of the first sub-pixel, the second sub-pixel and the third sub-pixel has a width which is half of a width of the pixel.

18. The display panel of claim 11, wherein the first sub-pixel, the second sub-pixel and the third sub-pixel are a red sub-pixel, a green sub-pixel and a blue sub-pixel, respectively.

19. The display panel of claim 13, wherein the first sub-pixel, the second sub-pixel and the third sub-pixel are a red sub-pixel, a green sub-pixel and a blue sub-pixel, respectively.

20. The display panel according to claim 11, wherein the first scan line and the second scan line has a scan frequency of 120 hz.
